(19) United States
(12) Patent Application Publication
(10) Pub. No.: US 2008/0231293 A1
(43) Pub. Date: Sep. 25, 2008

(54) DEVICE AND METHOD FOR ELECTRICAL CONTACTING FOR TESTING SEMICONDUCTOR DEVICES

(75) Inventors: Udo Hartmann, Neuried (DE); Juergen Weidenhoefer, Muenchen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: Qimonda AG, Muenchen (DE)

(21) Appl. No.: 12/051,015

(22) Filed: Mar. 19, 2008

(30) Foreign Application Priority Data
Mar. 19, 2007 (DE) 10 2007 013 062.9

(51) Int. Cl. G01R 31/26; H01L 23/48

(52) U.S. Cl. 324/719; 257/48; 257/E23.01

(57) ABSTRACT

A device and method for electrical contacting for the testing of semiconductor devices is disclosed. One embodiment provides for the electrical connection of the semiconductor device with a test system, including devices for the contacting of connection pins or contact pads of the semiconductor device to be tested. The devices for the contacting of the connection pins or the contact pads of the semiconductor device to be tested include contact holders with at least one exchangeable contact tip.

### CROSS-REFERENCE TO RELATED APPLICATIONS

This Utility Patent Application claims priority to German Patent Application No. DE 10 2007 013 062.9 filed on Mar. 19, 2007, which is incorporated herein by reference.

### BACKGROUND

One aspect relates to a device and to a method for electrical contacting for the testing of semiconductor devices.

The term semiconductor devices means in general integrated circuits as well as single semiconductors such as, for instance, analog or digital circuits or single semiconductors, as well as semiconductor memory devices such as, for instance, functional memory devices (PLAs, PALs etc.), and table memory devices (ROMs or RAMs, for example, SRAMs or DRAMs).

For the common manufacturing of a plurality of semiconductor devices, a wafer (a thin disc of monocrystalline silicon) is used. For the structuring of the later circuits, the wafer is subject to processing, such as, for instance, coating, exposure, etching, diffusion, and implantation processes. After the processing, the semiconductor devices are individualized in that the wafer is sawn apart, or scratched and broken, so that the individual semiconductor devices are then available for further processing.

After the structuring of the semiconductor devices (i.e. after the performing of the above-mentioned wafer processing), the devices available on the wafer may, for instance, be tested in wafer tests by using appropriate test devices. After the sawing apart (or the scratching and breaking, respectively) of the wafer, the devices that are then available individually are molded in a plastics mass, wherein the semiconductor devices obtain specific packages such as, for instance, TSOP or FBGA packages, etc.

Semiconductor devices are usually subject to comprehensive tests for examining their operability in the course of the manufacturing process in the semi-finished and/or finished state even prior to their incorporation in corresponding semiconductor modules. By using appropriate test systems or test cells, it is possible to perform test methods on wafer level even prior to the individualization of the semiconductor devices so as to be able to examine the operability of the individual semiconductor devices still on the wafer prior to their further processing.

One aspect serves, for example, to be used during the testing of the operability of semiconductor devices with appropriate test systems or test devices. In order to electrically connect the semiconductor device to be tested in a test station with the test system, a specific contact device, a semiconductor device test card—a probe card—is usually used. Needle-shaped connections or contact needles are provided at the probe card that contact the corresponding contact pads of the semiconductor devices to be tested.

By using the probe card it is possible to generate the signals required for testing semiconductor devices that are available on the wafer by using the test device connected with the probe card at a test station, and to introduce them into the respective contact pads of the semiconductor devices by using the contact needles provided at the probe card. The signals output in reaction to the input test signals by the semiconductor device at corresponding contact pads are in turn tapped by the needle-shaped connections of the probe card and, for instance, transferred to the test device via a signal line connecting the probe card with the test device, where an evaluation of the corresponding signals may take place.

During the testing on wafer level, the chip-internal voltages are, for instance, impressed from outside via current supply channels by a probe card of a test system and further via supply voltage contact points (contact pads) or connection pins on the chip. Via the contact tips of the probe card, the output voltage generated by the semiconductor device is also tapped at the corresponding connection pins or contact pads of the semiconductor device and transmitted to the test system so as to examine the operability of the semiconductor device.

For establishing the electrical contact between the individual connection pins or contact pads of the semiconductor device with the test system, the probe cards include contact holders that are equipped with sensitive contact tips that contact the connection pins or contact pads of the semiconductor device to be tested. The lifetime—or else service life—of the test device is therefore significantly influenced by the operability of the contact tips.

Furthermore, the electrical voltage applied at an external contact point of the semiconductor device may, due to contact disturbances between the probe card or the contact needle, respectively, of the test system and the external contact point of the semiconductor device, be distinctly lower than the supply voltage delivered by the test system. This may result in that the corresponding semiconductor device or at least particular switching blocks of the semiconductor device would, for instance, not be stressed sufficiently during a wafer level burn in method. If no contact is established between the probe card of the test system and the external contact point of the memory device, it is neither possible to apply a voltage via the corresponding contacting nor to detect it in a reliable manner, which would result in a falsification of the test result.

After a certain time, the contact tips are often disturbed in their function due to contamination. Since a cleaning of the contact tips is not possible or possible with difficulty only, the entire probe card usually has to be exchanged if the contact tips are worn. The usual exchange or the cleaning of defective probe cards is, however, related with high time consumption and high costs since no tests can be performed with the probe card during this time.

For these and other reasons, there exists a need for the present invention.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIGS. 1A, 1B, and 1C illustrate each a schematic representation of a contacting device according to one embodiment in different states.

FIGS. 2A and 2B illustrate each a schematic representation of a contacting device according to one embodiment in different states.

FIGS. 3A and 3B illustrate each a schematic representation of a contacting device according to one embodiment in different states.

FIG. 4 illustrates a schematic representation of a contacting device according to one embodiment.

FIGS. 5A and 5B illustrate each a schematic representation of the contacting device illustrated in FIG. 4 in different states.

FIGS. 6A and 6B illustrate each a schematic representation of a contacting device according to one embodiment in different states.

FIG. 7 illustrates a schematic representation of a contacting device according to one embodiment.

FIG. 8A a illustrates schematic representation of a contacting device according to one embodiment.

FIG. 8B illustrates a schematic representation of an impression on a contact pad which was generated by a contacting device according to the embodiment illustrated in FIG. 8A.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

One aspect provides a device for the electrical contacting of semiconductor devices for test purposes which prolongates the service life of the contacting device so as to reduce the operating costs of the test system altogether. One aspect consists in the reduction of the contact resistance between the device for the electrical contacting of semiconductor devices and the contact pads of the semiconductor devices.

In accordance with one embodiment, a device is provided that serves for the electrical contacting of a semiconductor device to be tested, and for the electrical connection of the semiconductor device with a test system with means for the contacting of connection pins or contact pads of the semiconductor device to be tested, wherein the means for the contacting of the connection pins or the contact pads of the semiconductor device to be tested include contact holders with at least one exchangeable contact tip.

Thus, it is possible to replace worn contact tips of the contacting device according to one embodiment with non-used contact tips. Furthermore, it is possible to use only particular contact tips for contacting the semiconductor device while other contact tips remain unused in reserve and are saved for later use. This way, the renewal cycles of the contacting devices according to one embodiment are prolongated, and thus the costs for testing semiconductor devices are reduced altogether.

With a device according to one embodiment, for instance, possible to use a first contact tip for contacting the connection pins or contact pads of the semiconductor device to be tested while a second contact tip remains unused. If the first contact tip has become useless, for instance, due to contamination, the first contact tip may in one embodiment be replaced with a second contact tip, for instance, and be used for contacting the connection pins or contact pads of the semiconductor device to be tested. This way, the renewal cycles of the contacting devices according to one embodiment can be prolongated, and thus the costs accruing during the manufacturing and testing of semiconductor devices may be reduced altogether.

In accordance with one embodiment, one or a plurality of particular contact tips may be selected for contacting the contact pads. This is, for instance, performed in that the contact holder is mounted to be pivotable and is adapted to be pushed with variable intensity in the direction of the semiconductor device to be contacted. To this end, the contact tips are arranged at the contact holder in an inclined manner consecutively in a row. This way, the contact pads of the semiconductor device are, for instance, only contacted by the foremost contact tip in the case of slighter pressure on the contact holder while the other contact tips at the contact holder above the contacting contact tips remain unused and can be saved for later use. Contrary to this, by a stronger pressure on the contact holder, the other contact tips at the contact holder, in addition to the foremost contact tip, may also contact in parallel one or a plurality of contact pads of the semiconductor device.

In accordance with one embodiment, the device includes means for the variable positioning of the contact holder at the probe card which are adjustable such that on contacting optionally only one or a plurality of particular contact tips can be get into contact with contact pads of the semiconductor device. By these means for the variable positioning of the contact holder it is, for instance, possible to adjust and determine a desired inclination with a particular horizontal and vertical position of the contact holder for the above-described purpose.

In accordance with one embodiment, the contact holder further includes a resilient bending element or joint which allows for a folding or bending movement of the contact holder. This resilient bending element or joint serves, for instance, for the variable positioning of the contact holder so as to determine in one embodiment a certain angle of inclination with a particular horizontal and vertical orientation of the contact holder and the contact tips arranged thereon. By using this contacting device according to one embodiment it is also possible to use more than one needle tip per contact holder consecutively or in parallel, depending on the design. By the applying of more than one needle tip it is also possible to reduce the electrical transition resistance between the probe card and the semiconductor device to be tested.

In accordance with one embodiment, the above-mentioned embodiments are solved by a device that serves for the electrical contacting of a semiconductor device to be tested, and for the electrical connection of the semiconductor device with a test system, including means for contacting connection pins or contact pads of the semiconductor device to be tested which include at least one contact mine, and driving means through which it is possible to drive the contact mine out of the contact holder.

In this embodiment, a contact mine is provided instead of the contact tip which is of a substantially pin-shaped design and consists of an electrically conductive material. The driving means may both assume a fixed state in which the contact mine is fixed, and a released state in which the contact mine is movable. Since the contact mine has the shape of a straight cylinder and is designed with a substantially constant diameter, it is adapted to be driven out of the contact holder in longitudinal direction by using the driving means. The contact mine may have a round or a polygonal cross-section so as to prevent a rotation of the contact mine in the contact holder about its longitudinal axis.

The driving means are, for instance, designed as a mechanic that is adapted to drive the contact mine out of the contact holder in line with the functioning principle of a mechanical pencil. This solution according to one embodiment has the advantage that the contact mine can be driven out of the contact holder on demand and/or depending on its abrasion. Thus, in the case of wear or break of a contact tip, it is no longer necessary to exchange the contact tip, but it is merely necessary to drive the contact mine out of the contact holder by the driving means, so that a new contact tip of the required length is available.

Furthermore, once the contact mine has been used completely, it is easy to be replaced by a new contact mine. Thus, the aspect of an exchangeable contact tip is also implemented in this solution according to one embodiment.

According to one embodiment, a method for the testing of semiconductor devices is presented by using a contacting device including a number of contact holders at which a plurality of contact tips are arranged for the electrical contacting of the contact pads of a semiconductor device to be tested, and for the electrical connection of the semiconductor device with a test system, wherein the method includes:

contacting the semiconductor device with a test system via the contact pads;

impacting the contacting device with a particular contact pressure in the direction of the contact pads to be contacted, wherein,

depending on the contact pressure, optionally one contact tip or a plurality of contact tips of a contact holder get into contact with the contact pads of the semiconductor device.

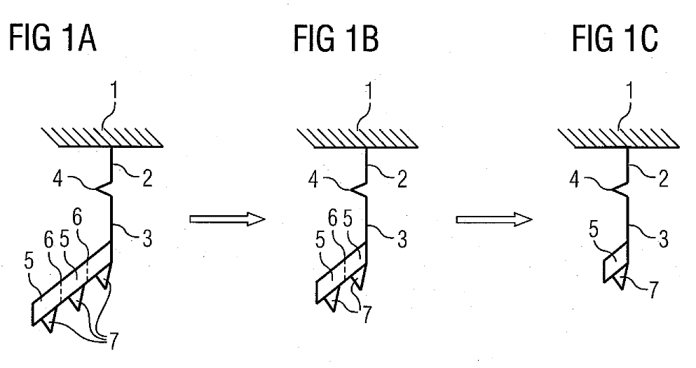

FIGS. 1A, 1B, and 1C each illustrate a schematic representation of a contacting device according to one embodiment in different states. FIGS. 1A, 1B, and 1C each illustrate a section of a probe card 1 that serves for the electrical connection of the semiconductor device to be tested with the test system. A number of contact holders 2 are arranged at the probe card 1, wherein only one contact holder 2 each is illustrated for better overview.

The contact holder 2 includes a free end 3 that is connected via a resilient bending element or joint 4 with the upper end of the contact holder 2, so that the free end 3 of the contact holder 2 is movable vis-à-vis the upper end and thus vis-à-vis the probe card 1. The free end 3 of the contact holder 2 includes a plurality of sections 5 that each carry a contact tip 7 at their bottom side. During the use of the contacting device according to one embodiment, one or a plurality of contact tips 7 may establish an electrical contact with contact pins or contact pads of a semiconductor device to be tested (not illustrated).

In one embodiment illustrated in FIGS. 1A, 1B, and 1C, the contact tips 7 are arranged at the free end 3 of the contact holder 2 consecutively in an inclined row. With this arrangement, only the foremost contact tip 7 gets into contact with a connection pad while the other contact tips 7 behind the foremost contact tip 7 remain unused and may be saved for following applications.

Between the individual sections 5 at the free end 3 of the contact holder 2, on which one contact tip 7 each is arranged, predetermined breaking points 6 are provided that are adapted to be broken by the application of an appropriate mechanical force effect. In one embodiment, the predetermined breaking points 6 may also be separated by a laser. By the breaking or separating of the breaking points 6 it is possible to separate the respective foremost section 5 from the free end 3 of the contact holder 2 and to remove the contact tip 7 arranged at the corresponding section 6.

In the state of the contacting device illustrated in FIG. 1A, three sections 5 are available at the free end 3 of the contact holder 2 at which one contact tip 7 each is arranged. In the contacting device illustrated in FIG. 1B, the foremost predetermined breaking point 6 was broken, and the outermost section 5 was removed along with the contact tip 7 arranged thereon. Thus, only two more sections 5 are available at the free end 3 of he contact holder 2, and the second, previously unused contact tip 7 may get into contact with the connection pad of a semiconductor device to be tested. In the state illustrated in FIG. 1C, the second predetermined breaking point 6 was broken, and the second section 5 was also removed along with the contact tip 7 arranged thereon. Thus, only one more section 5 is available at the free end 3 of the contact holder 2, and the third contact tip 7 may get into contact with the connection pad of a semiconductor device to be tested.

This way, the respective outermost contact tip 7 can be separated from the contact holder 2 along with the corresponding section 5 and be removed if the contact tip 7 has, for instance, become useless due to contamination. This process is to perform easier and with less effort than to exchange the entire contact holder 2 or the probe card 1 itself, so that the maintenance of the contacting device is reduced altogether and its service life is prolongated.

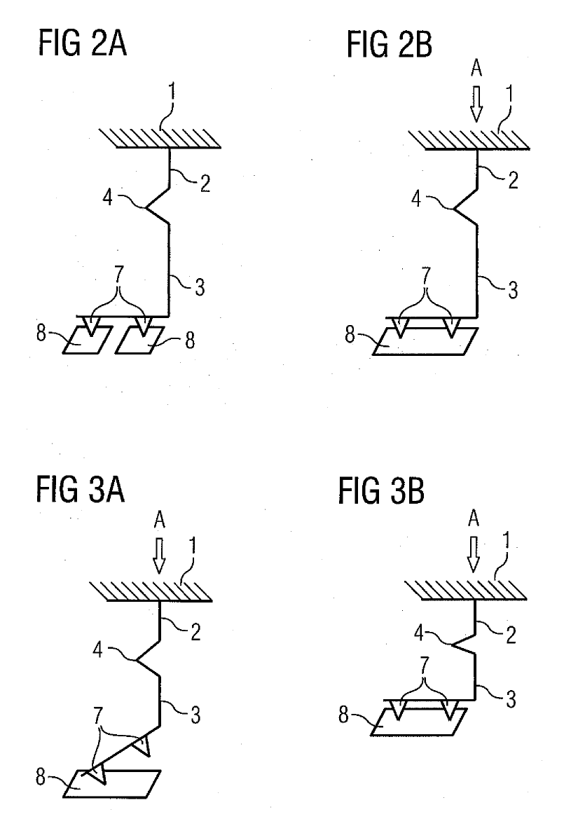

FIGS. 2A and 2B each illustrate a schematic representation of a contacting device according to one embodiment in different states. The structure of the contacting device illustrated in FIGS. 2A and 2B corresponds substantially to the structure of the device illustrated in FIGS. 1A, 1B, and 1C, so that reference may be made to the above description in this respect. The device illustrated in FIGS. 2A and 2B differs in that the free end 3 of the contact holder 2 includes a right angle, so that the contact tips 7 are positioned in one plane.

By the arrangement of the contact tips 7 in one plane, they are adapted to simultaneously establish an electrical contact with a connection pin or contact pad 8 of a semiconductor device to be tested (not illustrated). In the situation illustrated in FIG. 2A, the contact tips 7 each contact respective contact pads 8 of a semiconductor device which are separate from each other. In the situation illustrated in FIG. 2B, the contact tips 7 contact in parallel one single contact pad 8 of a semiconductor device to be tested. Thus, it is possible to establish the electrical contact between the semiconductor device to be tested and the test system even in a more reliable manner.

Moreover, the probe card 1 may be pressed on the contact pad 8 of the semiconductor device to be tested by applying an appropriate pressure in the direction of the arrow A, so that the electrical contact between the contact tips 7 and the contact pad 8 is still improved. In so doing, a damage of the contact pad 8 may, for instance, be prevented by the application of too high a contact pressure in the direction of the arrow A by the resilient bending element or joint 4 at the contact holder 2 in that the resilient bending element or joint 4 bends or folds elastically in correspondence with the contact pressure. The folding movement or the bending of the resilient bending element or joint 4 is reversible, so that it relaxes completely again after the strain and reassumes the initial position for a new application.

FIGS. 3A and 3B each illustrate a schematic representation of a contacting device according to one embodiment in different states. In the embodiment of the contacting device illustrated in FIGS. 3A and 3B, the contact tips 7 at the free end 3 of the contact holder 2 are arranged consecutively in an inclined row, similar to the embodiment illustrated in FIGS. 1A, 1B, and C. Thus, the free end 3 of the contact holder 2 has an obtuse angle.

In the state illustrated in FIG. 3A, the probe card 1 is pressed on a contact pad 8 of a chip to be tested only with a low contact pressure in the direction of the arrow A, so that only the foremost contact tip 7 gets into contact with the contact pad 8, and the resilient bending element or joint 4 at the contact holder 2 is stressed slightly only. In the state illustrated in FIG. 3B, the probe card 1 is pressed on the contact pad 8 with a stronger contact pressure in the direction of the arrow A, so that now both the front and the rear contact tip 7 get into contact with the contact pad 8, and the resilient bending element or joint 4 in the contact holder 2 is stressed more strongly. Thus, a plurality of contact tips 7 get into contact with the contact pad 8 under stronger contact pressure, so that a more reliable electrical contacting can be ensured.

To accomplish the above-described movement in the direction of the arrow A, either the probe card 1 or the contact holder 2 itself may, for instance, via a mechanic be moved in the direction of the surface of the contact pads 8 or away therefrom. Thus, a corresponding pressure is exerted on the probe card 1 in the direction of the arrow A, so that the contact holder 2 with the contact tips 7 is pressed on the contact pad 8 of the semiconductor device more strongly. In so doing, the wafer is positioned on a carrier, the chuck, which is adapted to be moved such that the wafer is placed in the desired position for contacting the semiconductor device to be tested.

Depending on the contact pressure of the contacting device on the surface of the contact pads 8, one or a plurality of contact tips 7 may thus be brought into contact with the contact pads 8. In so doing, a plurality of contact tips 7 at a contact holder 2 may jointly contact a contact pad 8, as is illustrated in FIG. 2B or in FIG. 3B, or a plurality of contact tips 7 may in parallel contact a plurality of separate contact pads 8, as is illustrated in FIG. 2A. On contacting of a plurality of separate contact pads 8, a low-ohmic connection between the contacted contact pads 8 which is useful for the test process may simultaneously be generated, which is not available without the contact tips 7 being applied. The applying of the contact tips 7 of a contact holder 2 on a plurality of separate contact pads 8 thus acts like a connecting switch between the contact pads 8.

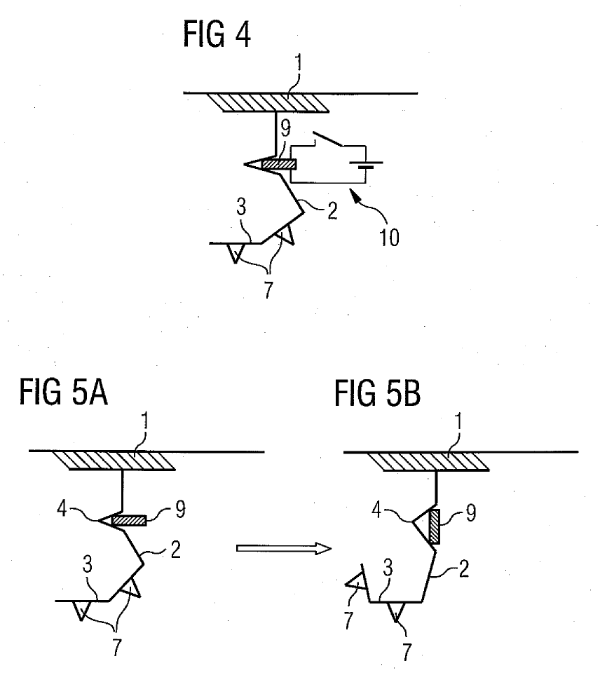

FIG. 4 illustrates a schematic representation of a contacting device according to one embodiment. In this embodiment, a number of contact tips 7 is arranged at the free end 3 of the contact holder 2 in different angular positions. The different angular positions of the contact tips 7 result from that the sections of the contact holder end 3 at which the contact tips 7 are arranged are angular to each other. This way, the free end 3 of the contact holder 2 describes a section of a polygon at the sectors of which a respective contact tip 7 is arranged. In one embodiment, the free end 3 of the contact holder 2 may also be designed in the form of a circle or a section of a circle, at the sectors of which contact tips 7 are arranged.

In the bend of the resilient bending or folding element 4, a piezo element 9 is provided which is adapted to be triggered via a circuit 10. Once the piezo element 9 is, via the circuit 10, impacted with an appropriate electrical voltage, the piezo element 9 expands and thus stretches the resilient bending or folding element 4 which thus opens at least partially. Due to the opening movement of the resilient bending or folding element 4 at the contact holder 2, the bottom portion of the contact holder 2 performs a pivoting movement.

FIGS. 5A and 5B each illustrate a schematic representation of the contacting device illustrated in FIG. 4 in different states. In the state illustrated in FIG. 5A, the piezo element 9 is controlled such by the circuit 10 that it contracts. Thus, the resilient bending or folding element 4 gets an acute angle and the lower angular portion 3 of the contact holder 2 is positioned such that the foremost contact tip 7 is oriented perpendicularly to the bottom and can get into contact with the contact pad of a semiconductor device to be tested. Simultaneously, a second contact tip 7 is positioned behind the front contact tip 7 such that it cannot contact the contact pad and is saved for later applications.

In the state illustrated in FIG. 5B, the piezo element 9 is controlled such via the circuit 10 that it expands, so that the resilient bending or folding element 4 opens. Thus, the bending or folding element 4 gets a less acute angle, and the lower angular portion 3 of the contact holder 2 is positioned such that the second contact tip 7 is oriented perpendicularly to the bottom and can get into contact with the contact pad of a semiconductor device to be tested. Simultaneously, the front contact pad 7 is positioned such that it can no longer contact the contact pad. Thus, a used contact tip 7 may be removed and an unused contact tip may be used for contacting the semiconductor device to be tested.

Once the first contact tip 7 has become useless, for instance, due to wearing, it may be removed by the above-described pivoting mechanism of the contact holder 2, so that the second contact tip 7 is placed in the position of the first contact tip 7. In a subsequent test process, the contact pads or connection pins of the semiconductor device to be tested are then contacted only by using the second contact tip 7 of the device according to one embodiment. Thus, the service life of the test device can again be prolongated, and the reliability of the electrical contacting between the semiconductor device and a test system via the contact tips 7 of the probe card 1 can be improved.

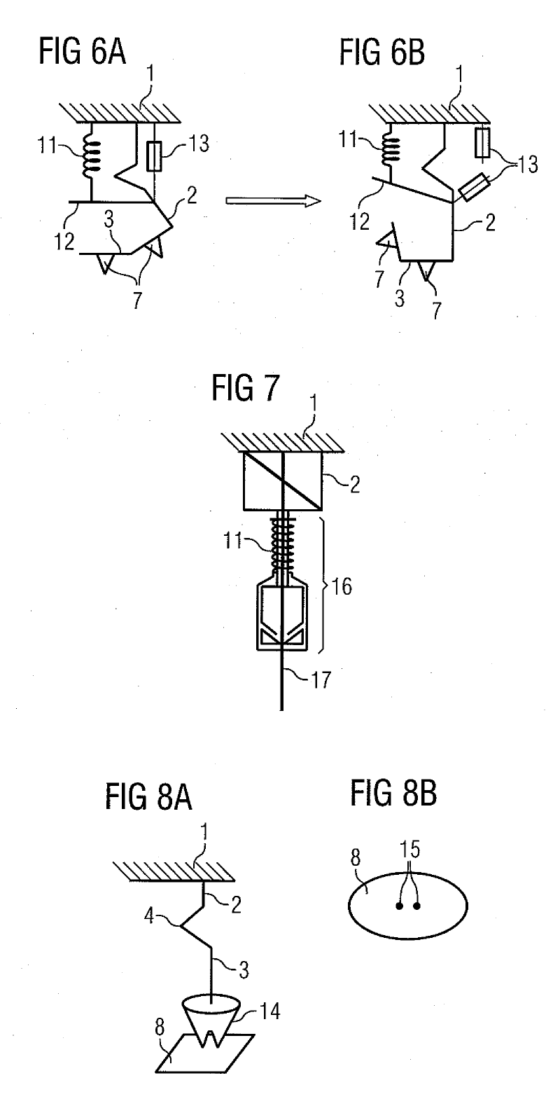

FIGS. 6A and 6B each illustrate a schematic representation of a contacting device according to one embodiment in different states. In this embodiment, an electromechanical fuse 13 is provided in the bend of the resilient bending or folding element 4 which is adapted to be broken by being impacted with an appropriate current. The electromechanical fuse 13 is, on the one hand, attached to the bottom of the probe card 1 and, on the other hand, connected with the free end of the contact holder 2. On the opposite side of the resilient bending or folding element 4, a spring element 11 is provided which is, on the one hand, attached to the bottom of the probe card 1 and, on the other hand, connected with the free end of the contact holder 2 via a lever arm 12.

The free end of the contact holder 2 is, like in previous embodiments, angular, wherein contact tips 7 are arranged on the portions that are angled towards each other. In the state illustrated in FIG. 6A, the spring element 11 is biased, and the electromechanical fuse 13 is intact. In this state, the lower angular portion 3 of the contact holder 2 is positioned such that the front contact tip 7 at the free end 3 of the contact holder 2 is oriented perpendicularly to the bottom and can get into contact with a contact pad. A second contact tip 7 at the free end 3 of the contact holder 2 is oriented such that it cannot get into contact with a contact pad and remains unused for a later application.

As soon as the fuse 13 is fused by the application of a sufficiently large current, the mechanical holding effect of the fuse 13 is cancelled, the spring element 1I1 resigns to its bias, and contracts. Thus, the spring element 11 pulls at the lever arm 12 and swivels the lower portion 3 of the contact holder 2 in a new position that is illustrated in FIG. 6B. In this situation illustrated in FIG. 6B, the lower angular portion 3 of the contact holder 2 is positioned such that the second contact tip 7 at the free end 3 of the contact holder 2 is oriented perpendicularly to the bottom and can get into contact with a contact pad while the front contact tip 7 at the free end 3 of the contact holder 2 is oriented such that it can no longer get into contact with a contact pad.

The mechanic of the embodiment of the contacting device according to one embodiment as illustrated in FIGS. 6A and 6B consequently serves for the generation of a pivoting movement of the contact holder 2 so as to bring its angular end 3 and the contact tips 7 arranged thereon in a particular angular position, and to thus make a selection of which contact tips 7 are used for the contacting of the semiconductor device to be tested.

FIG. 7 illustrates a schematic representation of a contacting device according to one embodiment. In this embodiment, a contact tip 7 of the probe card 1 is designed in the form of a contact mine 17. Furthermore, mechanical drive means 16 are provided at the contact holder 2, through which the contact mine 17 can be driven out of the contact holder 2.

For this purpose, the contact mine 17 is substantially designed pin-shaped and is manufactured of an electrically conductive material. The mechanical drive means 16 may assume both a fixed state in which the contact mine 17 is fixed, and a released state in which the contact mine 17 is adapted to be shifted in longitudinal direction. Thus, the contact mine 17 is adapted to be driven out of the contact holder 2 by the drive means 16 on demand.

The drive means 16 are preferably designed as a mechanic that is adapted to drive the contact mine 17 out of the contact holder 2 in line with the functioning principle of a mechanical pencil. This solution according to one embodiment has the advantage that the contact mine 17 is adapted to be driven out of the contact holder 2 on demand or depending on its wear. By the driving of the contact mine 17 out of the contact holder 2, a certain adaptation of the distance between the probe card 1 and the contact pad 8 to be contacted may also be performed.

The demand for the pushing forward of a particular length of the contact mine 17 may, for instance, be determined by optical control, contact test, or Z-height determination. In this embodiment of the contacting device, strongly abrasive cleaning methods may also be used since it is possible to push the contact mine 17 out of the contact holder 2 by the respectively abraded length by using the drive mechanism 16. Once the contact mine 17 has been used or worn, it is easy to be exchanged by a new contact mine 17.

FIG. 8A illustrates a schematic representation of a contacting device according to one embodiment. In this embodiment, a contact tip is formed at a contact holder 2 with a tip pair 14, so that two contact tips 7 can simultaneously contact the contact pad of a semiconductor device to be tested. In one embodiment, the contact tip may also be designed with a plurality of tip pairs 14 or “mini spikes”, respectively, so that a plurality of small contact tips can simultaneously contact the contact pad of a semiconductor device to be tested. To ensure a regulated contact pressure of the contact tip 14 on the contact pad 8, this embodiment is also provided with a resilient bending or folding element 4 at the contact holder 2 which avoids or assimilates, respectively, an excessive contact pressure of the probe card 1 on the contact pad 8.

FIG. 8B illustrates the schematic representation of an impression on the contact pad of a semiconductor device that was contacted by a contacting device according to the embodiment illustrated in FIG. 8A. As is illustrated in FIG. 8B, two impressions are positioned side by side on the surface of the contact pad, which were generated by the twin tips of the contact tip pair 14 during contacting. By the use of a double or multi-contact tip 14, it is also possible to undercut the electrical resistance of an individual contact tip. By the use of contact tip pairs 14 with double or multi-tips, it is consequently possible to achieve a more reliable contacting of the contact pad 8.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A device that serves for the electrical contacting of a semiconductor device to be tested and for the electrical connection of the semiconductor device with a test system, comprising:
means for the contacting of connection pins or contact pads of the semiconductor device to be tested,
wherein the means for the contacting of the connection pins or the contact pads of the semiconductor device to be tested comprise contact holders with at least one exchangeable contact tip.

2. The device of claim 1, wherein the contact holder comprises a free end comprising a plurality of sections at which at least one respective contact tip is arranged.

3. The device of claim 2, wherein the contact tips are arranged at the free end of the contact holder in an inclined manner consecutively in a row and wherein only the outermost contact tip at the free end of the contact holder is in the position of contacting a contact pad of the semiconductor device to be tested.

4. The device of claim 3, wherein respective predetermined breaking points are provided between the individual sections at the free end of the contact holder and wherein sections are separable from the free end of the contact holder by the separating of the predetermined breaking points, in order to remove the contact tips arranged on the corresponding sections.

5. The device of claim 2, wherein, by the removing of the outermost section at the free end of the contact holder, the respectively adjacent contact tip at the free end of the contact holder gets in a position in which it can contact a contact pad of the semiconductor device to be tested.

6. The device of claim 2, wherein the free end of the contact holder is angled such that the contact tips arranged at the free end of the contact holder are positioned in a plane and can get in parallel into contact with a contact pad.

7. The device of claim 2, wherein the free end of the contact holder has an obtuse angle, wherein a number of contact tips are arranged in different orientations at the free end of the contact holder, and wherein the sections at the free end of the contact holder at which the contact tips are arranged are angled to each other.

8. The device of claim 2, wherein the free end of the contact holder is at least partially formed in the shape of a polygon, a circle, or as a portion of a circle at the sections of which a respective contact tip is arranged.

9. The device of claim 2, wherein, by the pivoting movement of the contact holder, a respective particular contact tip at the free end of the contact holder gets in a position in which it can contact a contact pad of the semiconductor device to be tested.

10. The device of claim 2, wherein the free end of the contact holder is connected with an upper portion of the contact holder via a resilient bending element or a joint that bends reversibly or folds elastically in correspondence with a contact pressure on the contact pad.

11. The device of claim 10, wherein a piezo element is arranged at the resilient bending element which is adapted to be controlled such that it expands or contracts, wherein the resilient bending element opens once the piezo element expands, and wherein the resilient bending element closes once the piezo element contracts.

12. The device of claim 10, wherein an electromechanical fuse is provided which is connected with the free end of the contact holder such that it predetermines a particular position of the resilient bending element, wherein the electromechanical fuse can be broken by the application with an appropriate current.

13. The device of claim 12, wherein a spring element is provided which is connected with the free end of the contact holder such that the free end of the contact holder with the contact tips arranged thereon performs a swiveling movement once the electromechanical fuse has been broken.

14. The device of claim 12, comprising wherein, with an intact electromechanical fuse, a first contact tip at the free end of the contact holder is in a position in which it can contact a contact pad of the semiconductor device to be tested, and wherein, with a broken electromechanical fuse, a second contact tip at the free end of the contact holder is in a position in which it can contact a contact pad of the semiconductor device to be tested.

15. The device of claim 2, wherein a mechanic is provided which enables a swiveling movement of the contact holder so as to place the free end thereof and the contact tips arranged thereon in a particular angular position, and wherein, by the swiveling movement of the contact holder, a particular contact tip or a plurality of contact tips is/are positioned such that they can contact a contact pad of the semiconductor device to be tested.

16. The device of claim 1, wherein the contact tip comprises a double or multi-contact tip.

17. The device of claim 1, wherein the means for contacting the connection pins or the contact pads of the semiconductor device to be tested comprise a contact holder with at least one contact mine, and wherein drive means are provided through which the contact mine is adapted to be driven out of the contact holder.

18. The device of claim 17, wherein the contact mine is substantially formed pin-shaped and is manufactured of an electrically conductive material.

19. The device of claim 17, wherein the mechanical drive means may assume a fixed state in which the contact mine is fixed, or a released state in which the contact mine is movable in the contact holder, and wherein the drive means comprise a mechanic through which the contact mine is adapted to be driven out of the contact holder in line with the functioning principle of a mechanical pencil.

20. The device of claim 17, wherein the contact mine is adapted to be driven out of the contact holder depending on its wear and wherein the contact mine has a substantially round or polygonal cross-section.

21. A method for testing semiconductor devices using a contacting device comprising a number of contact holders at which a plurality of contact tips are arranged for the electrical contacting of the contact pads of a semiconductor device to be tested, and for the electrical connection of the semiconductor device with a test system, the method comprising:
contacting the semiconductor device with a test system via the contact pads;
impacting the contacting device with a particular contact pressure in the direction of the contact pads to be contacted,
wherein depending on the contact pressure, optionally one contact tip or a plurality of contact tips of a contact holder gets/get into contact with the contact pads of the semiconductor device.

22. The method of claim 21, wherein a plurality of contact tips of a contact holder jointly contact a contact pad of the semiconductor device to be tested.

23. The method of claim 21, wherein a plurality of contact tips of a contact holder in parallel contact separate contact pads of the semiconductor device to be tested and thus establish an electrical connection between the separate contact pads.

24. The method of claim 21, wherein, with a low contact pressure of the probe card on the contact pads, only the foremost contact tip at the free end of the contact holder gets into contact with the contact pad and wherein, with a stronger contact pressure of the probe card on the contact pads, a plurality of contact tips at the free end of the contact holder get into contact with one or a plurality of contact pads.

25. The method of claim 21, comprising determining the demand for driving a contact mine out of the contact holder by optical control, contact test, or Z-height determination.
